(19) United States
(12) Patent Application Publication
(10) Pub. No.: US 2007/0017443 A1
(43) Pub. Date: Jan. 25, 2007

(54) Wireless operator interface for material application system

(76) Inventors: Cynthia Skelton-Becker, Rocky River, OH (US); Joseph Schroeder, North Royalton, OH (US)

Correspondence Address: CALFEE, HALTER & GRISWOLD, LLP, 800 SUPERIOR AVENUE, SUITE 1400, CLEVELAND, OH, 44114, US

(21) Appl. No.: 10/566,870

(22) PCT Filed: Jun. 14, 2004
(86) PCT No.: PCT/US04/18843

§ 371 Date: Feb. 2, 2006

Related U.S. Application Data
(60) Provisional application No. 60/481,251, filed on Aug. 18, 2003.

(51) Int. Cl. B05C 11/00; C23C 16/52

(52) U.S. Cl. 118/712; 427/180; 118/308; 118/663; 427/8

(57) ABSTRACT

Operator interface provides identification of one or more operational functions, each at an operational location, to an operator via an access device. The access device may have a wireless connectivity with the operational functions, and presents menus that are specific to the identified function. The access device optionally provides data, control functions, recipes, menus and so on to the operator. In this manner, an operator can exercise local control of the operational functions at different operational locations, thereby reducing lost time and energy transferring between the operational locations.

### RELATED APPLICATION

This application claims the benefit of United States provisional patent application Ser. No. 60/481,251 filed on Aug. 18, 2003 for WIRELESS OPERATOR INTERFACE FOR FINISHING SYSTEM, the entire disclosure of which is fully incorporated herein by reference.

### TECHNICAL FIELD OF THE INVENTION

The present invention relates to powder and liquid material application apparatus. More particularly, the invention relates to augmenting a control system for such an apparatus with a portable access device.

### BACKGROUND OF THE INVENTION

Powder and liquid coating materials are commonly applied to surfaces of target objects by spraying or otherwise dispensing the material in a selectable pattern. A typical powder spray apparatus, for example, can include one or more spray guns, a spray gun mover and/or oscillator, a powder spray booth, a powder supply, a control console, and often a powder overspray collection and/or reclamation system. Such apparatus are well known and described in the following exemplary U.S. Pat. Nos. 5,167,714; 5,482,556; 5,566,042; and 6,021,799, the entire disclosures of which are fully incorporated herein by reference.

The material application device may be electrostatic or non-electrostatic. In an electrostatic device, a high voltage electrode is used to apply an electrostatic charge to the material to improve the transfer ratio of material adhering to the target object. Application devices also typically include a triggering mechanism that is used to control the flow of material through the device. Such devices may be manually operated or electronically controlled such as with a robotic mechanism and/or appropriate electronic control arrangements.

In a non-limiting example of a powder application system, a typical spraying operation is performed in a powder spray booth. The primary objective of using the booth is for powder overspray containment. Some powder booths are equipped or may be equipped with powder collection and recovery systems that collect powder overspray and either transfer the collected powder to a holding container or return the collected powder to the powder supply for continued use.

The spray gun(s) can be supported in the spray booth either on a stationary platform or on a movable platform. The movable platform may include a gun mover that not only can set and change the horizontal position of the gun spray nozzle relative to the target, but may also include the function of vertical movement of the gun(s).

Each spray gun receives a flow of powder coating material from a powder supply or feed center. Powder for a spraying operation is held in a hopper or other suitable container. Powder is drawn from the hopper by operation of a pneumatic powder feed pump. The powder pump typically operates from one or more pressurized air supplies, and feeds powder to the gun via a powder feed hose or tube.

The powder supply in the hopper is also typically fluidized by a flow of air through the powder, either through the floor of the hopper or a supply of air that fluidizes the upper portion of the powder. Virgin powder may be loaded into the hopper either manually or by operation of an automated powder transfer apparatus that transfers powder from a powder drum or other powder supply container to the hopper. In an automated powder transfer apparatus, sensors may be used to detect the powder level in the hopper and also to monitor the transfer operation.

It is thus evident that in a conventional material application system, such as a powder spraying system, there is a large number of functions and operations that are controlled, either manually, automatically or a combination of the two. These control and operational functions may be physically separated on a shop floor or otherwise within a facility. Even though a central control console may be utilized, an operator typically still must walk around to the various locations in order to adjust settings, monitor activity, implement color change procedures and so on. The need to walk back and forth between a central control console and one or more of the functional locations is annoying and time consuming. The ever increasing demand to shorten color change times also underscores the inefficiency of even having to walk a short distance between operational locations on a shop floor.

It is desired, therefore, to provide new methods and apparatus for material application systems that facilitate local operator interface at one or more operational locations associated with a material application system.

### SUMMARY OF THE INVENTION

The invention contemplates an arrangement in a material application system by which an operator or other user can access data and control functions locally at various operational locations of the system using a hand held access device. In this manner, the operator can make local adjustments or take readings or generate commands while at the operational location without having to return back to the control console or other operational locations. In order to provide local access, in one embodiment, location specific operational and function specific identifiers are provided. In an exemplary embodiment the identifiers have wireless connectivity with the access device. Alternatively, the access device can be connected to a docking station, cradle or other suitable interface at the one or more operational locations to access the identifiers.

The identifiers can be detected or recognized by the access device, with an appropriate menu displayed for the operator that is pertinent to the operational function associated with the recognized identifier. The operator can then use the menu or other control logic associated with the access device to perform desired operations. In one embodiment each identifier transmits an identification signal that is uniquely associated with a specific operational function, usually at a specific operational location. For example, but not by way of limitation, when the operator is in the proximity of the spray booth (the operational location), the access device detects an identifier associated with a spray gun (the operational function). Other identifiers can be detected such as may be associated with a gun mover for example. In one embodiment, the access device presents a menu of all identifiers recognized at a particular operational location to allow the operator to select and access the device of interest. In another embodiment an override feature may be used to allow the operator to access an operational function that is at a location other than the operator's present location, such as for example, access back to the control console without having to leave the spray booth area.

In accordance with another aspect of the invention, the identifiers may be detected by the access device by transmitting a unique identification signal to the access device. Alternatively, the access device may transmit a signal that is locally detected, thus activating a sensor or other device that then transmits an identifier back to the access device. In either embodiment, the access device is notified by wireless or other connectivity that the operator is within a sensing distance of the identifier and its associated operational functional.

In accordance with another aspect of the invention, the access device has wireless connectivity to each of the identifiers associated with the operational functions, such as for example by IR, radio frequency, ultrasonic or other suitable wireless technology. A conventional wireless network, such as for example, a WAN, LAN, Bluetooth type network, IEEE 802 network and so on may be use to provide the wireless connectivity. The access device may be programmed to facilitate operator control of the system as desired, by including interface logic and/or control logic. In various embodiments the interface logic may permit the operator to adjust settings, collect data, exchange commands with the central control system and so on. In a specific embodiment, the access device presents a visual menu to the operator that is based on the detected and selected operational function at each operational location.

The invention further contemplates the methods associated with and embodied in the design and/or use of such an arrangement as described above. In one embodiment, a method is provided for controlling a material application system, comprising the steps of providing two or more material application operational functions with each operational function being located at a respective operational location so that at least two of the operational locations are physically separated from each other by a distance such that an operator traverses the distance between the locations; associating a unique wireless identifier with each operational function; and using wireless connectivity for an operator to detect each identifier These and other aspects and advantages of the present invention will be apparent to those skilled in the art from the following description of the preferred embodiments in view of the accompanying drawings.

### BRIEF DESCRIPTION OF THE DRAWINGS

The invention may take physical form in certain parts and arrangements of parts, preferred embodiments and a method of which will be described in detail in this specification and illustrated in the accompanying drawings which form a part hereof, and wherein:

FIG. 1 is a simplified schematic representation of a typical material application system as a floor plan and utilizing the present invention;

FIG. 2 is a functional block diagram of a communication arrangement utilizing the present invention;

FIGS. 3A and 3B illustrate a functional block diagram for a control function in accordance with the invention; and

FIGS. 4 and 5 illustrate an exemplary menu screens useful with the present invention.

### DETAILED DESCRIPTION OF THE PREFERRED EMBODIMENTS

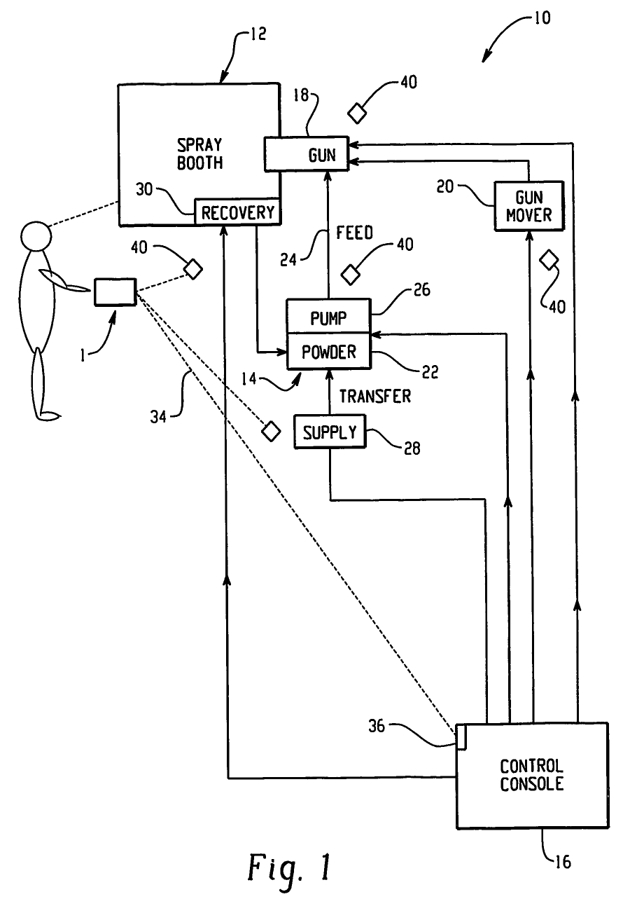

With reference to FIG. 1, in an exemplary embodiment, the present invention is illustrated as embodied in a material application system, such as, for example, a typical powder spraying apparatus 10 of the type that includes a powder spray booth 12 in which an object (not shown) is to be sprayed with a powder coating material 14. The application of powder to the object is generally referred to herein as a powder spraying or coating operation, however, there may be any number of control functions, steps and parameters that are controlled and executed before, during and after powder is actually sprayed onto the target. Therefore, as used herein, the terminology of controlling a material application operation should be construed in it broadest sense to include any one or more of selecting, executing, controlling, adjusting, changing or modifying one or more aspects of a material application process and/or control of the booth environment. Thus it is contemplated, for example, that the invention may be used for controlling any one or more of a wide variety of parameters and functions of a spraying operation. These may include, but are not limited to, gun triggering control, gun power control, powder feed control, powder supply control and gun position control, either as part of a manual operation, an automatic operation or a combination of the two, spray booth air flow control and color change operations. These features are included herein in connection with an exemplary description of the present invention but such description should not be construed in a limiting sense. The invention will find application in any material application system in which it is desired to control one or more aspects of the application operation. Moreover, while the described embodiments herein are presented in the context of a powder application apparatus, those skilled in the art will readily appreciate that the present invention may be used in a liquid application or dispensing systems. The specific design and operation of the material application system selected provides no limitation on the present invention except as otherwise expressly noted herein.

Additionally, various aspects of the invention are described and illustrated herein as embodied in combination in the exemplary embodiments. These various aspects however may be realized in many alternative embodiments, either alone or in various combinations and sub-combinations thereof. Still further, various alternative embodiments as to the various aspects and features of the invention, such as alternative materials, structures, configurations, methods, devices and so on may be described herein, but such descriptions are not intended to be a complete or exhaustive list of available alternative embodiments, whether known or later developed. Those skilled in the art may readily adopt one or more of the aspects of the invention into additional embodiments within the scope of the present invention even if such embodiments are not expressly disclosed herein. Additionally, even though some features and aspects of the invention may be described herein as being preferred arrangement or method, such description is not intended to suggest that such feature is required or necessary unless so expressly stated. Still further, exemplary or representative values and ranges may be included to assist in understanding the present invention however, such values and ranges are not t be construed in a limiting sense and are only intended to be critical values if so expressly stated.

The apparatus 10 further typically includes one or more application devices, such as spray guns 18 that are either fully or partially positioned within the spray booth 12. The guns may individually or collectively be manually triggered or automatic, and furthermore may be electrostatic or non-electrostatic in operation. The guns 18 may individually or collectively be mounted on a stationary support or mounted on a gun mover 20 as is known. Manually operated gun may also be used. Each gun 18 (for clarity only one is shown in FIG. 1) receives a powder feed from a powder hopper 22 by way of a powder feed hose 24. A pneumatic pump 26 draws the powder 14 from the hopper 22 and feeds the powder to the gun 18 via the feed hose 24. A powder supply 28, for example a powder drum, holds a fresh supply of powder that can be manually or automatically transferred to the hopper 22. The powder booth 12 may include a powder collection and recovery system 30 that collects powder overspray and either transfers it to a container or recycles the powder back to the hopper 22 as illustrated in FIG. 1.

In the apparatus of FIG. 1, the control console 16 is typically used as a central control location for the operator to make adjustments, set parameters and in general to control a spraying operation. The console 16 may include a programmable controller or other electronic logic circuit, and a variety of devices and interfaces for controlling operation of the guns 18, the gun mover 20, the powder pumps 26 and supply 28, and the recovery system 30. The specific design of the console 16 will be determined by the actual spraying system 10 design, and thus may include all or fewer than the illustrated features, or additional features. Again, specific details of a suitable control console and system are provided in the referenced patents and are otherwise well known to those skilled in the art.

Those skilled in the art will readily appreciate that the schematic of FIG. 1 is greatly simplified and is used solely for the purpose of providing an example of one of any number of material application systems and apparatus that the present invention will find utility in combination. More or fewer components of the system 10 may be used with the present invention. Details of the individual components of FIG. 1 are provided in the above-referenced patents, among others.

The present invention contemplates the use of an access device 1 to augment the control functions, parameters and other features of the control console 16 used in the material application system 10. As illustrated in FIG. 1, the access device 1 is preferably but not necessarily realized in the form of a programmable hand-held wireless device, such as, for example, a PDA. In accordance with one aspect of the invention, the access device 1 provides an optional wireless link between the operator and the control console 16, as represented in FIG. 1 with the dashed line 34. The wireless link permits the operator to send instructions to the control console 16 while being stationed at, in or near the powder spray booth 12 or other remote location relative to the console 16. In this manner, the operator can observe a spraying operation and send instructions to the control console 16 to change one or more parameters or functions, and at the same time observe the effects at the booth 12. The control console 16, for example, may be remotely located at a distance from the spray booth 12, even as far as 10 or 20 feet just to give an example. The actual distances will vary at each site and will only be limited by the effective range of the wireless access device 1. As a general aspect of the invention, however, “remote distance” or “remote location” means any distance or location beyond arm's length and not greater than a maximum range of the selected remote transmitter device 1, or in some cases remote distance or location can be any position in which a function, operation or control is not visually accessible.

In accordance with another aspect of the invention, the access device I communicates with one or more identifiers 40. The number and location of the identifiers is a matter of design choice based on the design and layout of the material application system 10, and which operational functions it is desired to locally control.

As used herein, the term operational function refers generically to any one or more devices, functions, controls and so on that form part of the application system 10. For example, but not by way of limitation, for the system of FIG. 1 an operational function may be the gun mover 20, the recovery system 30, the spray booth 12, the supply 28, the gun 18 and so on. For each operational function to which local access is desired, an identifier 40 may be provided.

Each operational function is physically located at an operational location somewhere on the shop floor. The operational locations may be separated by a few feet or many feet. Prior to the invention, an operator might have to traverse substantial distances to make adjustments, monitor quality, effect a color change operation and so on. This would require the operator to make a local observation at on of the operational locations and then traverse back to the control console 16. However, by using the present invention an operator can now make adjustments and changes locally to an operational function at an operational location. The identifiers 40 provide function identification and can communicate with the access device 1. Preferably, but not necessarily, wireless communication is used to link each identifier 40 with the access device 1. Alternatively, a docking station, cradle or similar wired link may be used. For example, the access device 1 may interface through a RS-232 port, USB port, IEEE 1394 port, serial and parallel ports and so on to name a few.

When an operator approaches within range or sensing distance of one or more of the identifiers 40, the access device 1 detects the identification signal being transmitted by the identifiers 40. Each identification signal is preferably unique so that upon detection the access device 1 provides a visual indication to the operator of the operational function now accessible to the operator. The access device 1 includes identification logic that detects the identifier 40 that is sending the signal.

While the exemplary embodiment uses an identifier 40 that transmits an identification to the access device 1, alternatively the access device 1 may be programmed to transmit an interrogation signal. When the interrogation signal is received by an identifier 40, that identifier 40 can then send back to the access device its identification signal.

Due to the sometimes complex nature of material application systems, as well as sometimes relatively close proximity of two or more operational functions (for example, a gun and a gun mover), the access device 1 might detect two or more identifiers at the same time. In such a case, the access device is programmed to include selection logic to allow an operator to select which operational function the operator wishes to interface with. This selection may be made, for example, from a simple selection menu presented to the operator on a visual screen that is part of the access device 1.

Once the access device 1 has established communication with an identifier 40, in accordance with the invention, control logic in the access device 1 presents a menu to the operator for exchanging or receiving data, adjustments, controlling the operational function and so on. Thus, the access device 1 recognizes where it is physically within the plant and presents a menu that is specific to the operational function selected by the operator. In this manner, the operator can execute local control of the operational function at the associated operational location, so long as the operator remains within the range of communication.

Although it is contemplated that the operator typically will exercise local control at an operational location, the access device 1 may optionally include override logic that allows the operator to communicate with an operational function that is beyond the sensing distance of that function. For example, a wireless network may be used to establish such communication. A typical example would be to provide available communication to the control console 16 from any of the operational locations.

In accordance with another aspect of the invention, the access device 1 may include control logic and an encoder that converts one or more pushbutton commands into an electronic signal that is converted to a transmitted signal. Alternatively, commands may be entered through touch screen operation with a stylus, or with an attached keyboard. The signal is detected at a receiver that detects the signal and decodes or converts it to an electronic instruction that is then processed by appropriate electronics in the control circuits associated with the operational function.

The access device 1 is realized in the form of a programmable device such as a PDA that can also communicate with the control console 16 and identifiers 40 via a wireless link such as IR transmission. The PDA typically will be a software based device that may include other functionality not necessarily related to operation of the material application apparatus 10. In this context then, the PDA version is considered to be a non-dedicated device because the device might be used for other features such as e-mail, calendars and so on as is typical in a conventional PDA device such as the PALM PILO™ series of PDA's. Dedicated devices may alternatively be used including proprietary or other custom programming.

In the exemplary embodiment, wireless connectivity is used to establish communication between the access device 1 and each of the identifiers 40. While the identifiers 40 can be simple receivers and transmitters, it is further contemplated that an identifier 40 can be incorporated into a local control circuit for its associated operational function. In this way, not only can the operator identify the operational function being accessed, but also can execute control logic through the access device 1 to control locally the operational function. This can also be accomplished with a direct (i.e. non-wireless) connection via a cradle, docking station and so on.

Wireless connectivity may be established in any number of ways, including, but not limited to, IR IrDA), RF, LAN, WAN, 802.11 (Wi-Fi) networks, IEBEE 1394 networks, Bluetooth™ networks and so on to name a few. Still further, distributed communication may be realized by CAN networks or other proprietary protocol networks.

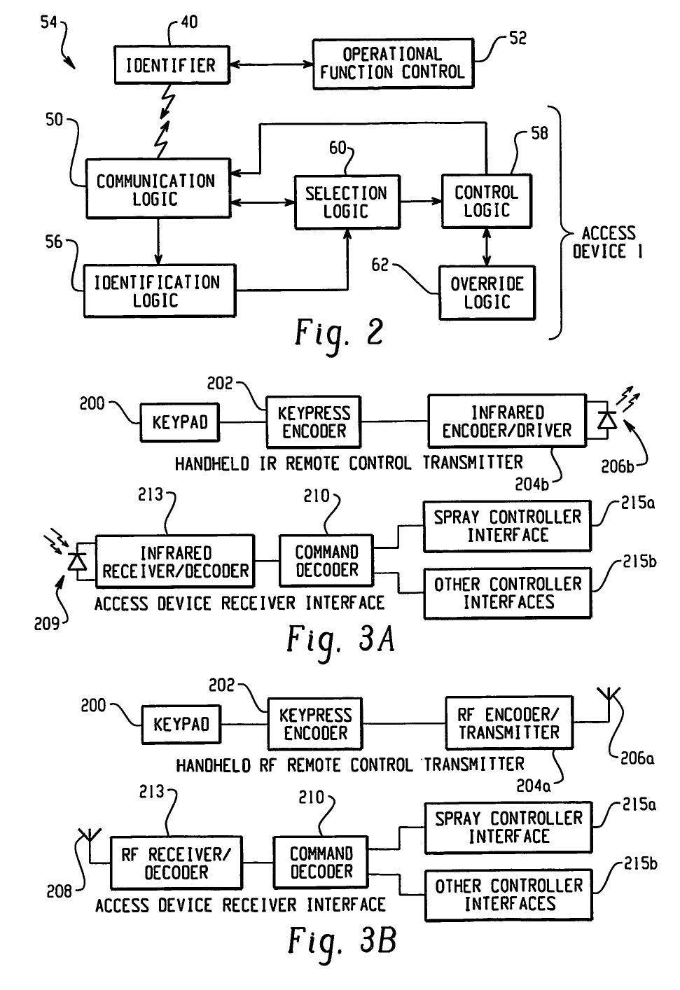

With reference to FIG. 2, in an exemplary embodiment the access device 1 may be programmed with software in a conventional manner and includes communication logic 50 that allows the device 1 to communicate with the operational function 52. In this example, communication is established via the identifier 40 which may include a transmitter/receiver circuit for exchanging data commands and control signals with the access device 1 over a communication link 54. Although the link 54 is illustrated as a wireless link, it need not be as noted hereinabove. The identifier 40 interfaces with the operational function control 52 to allow the access device 1 to communicate therewith.

The access device communication logic receives an identification signal from the identifier 40. Identification logic 56 decides the identification signal so that the control logic 58 may present an appropriate menu or screen to the operator for controlling operation of the operational function 52. Optional selection logic 60 may be used for systems in which it is likely that more than one identifier 40 may be detected at an operational location or from any other location within sensing distances of the operational functions. Override logic 62 may optionally be included to allow an operator to communicate with the operational functions, particularly the control console 16 for example, -even when beyond the sensing range of the associated identifier, provided communication can be established via an appropriate wired or wireless network. For example, wired or wireless links to a CAN system would be effective.

The access device 1 may be programmed to provide the operator with a variety of data collection, monitoring, and/or control functions. The specific options presented to the operator will be based on each operational function and the level of sophistication of the control logic built into the access device 1. These are therefore largely a matter of design choice. A typical example could be to present to an operator a recipe to follow for every color change operation. Other options might be local diagnostics, parts identification (e.g. different parts being sprayed), gun control parameters such as material identification, air pressure settings, current and voltage settings, trigger times, setup menus and parameters and so on. This is but a small listing of the types of control and monitoring features that can be carried out by use of the present invention. One of the key aspects of the invention, therefore, is that an operator can approach an operational function, and the access device will identity where the operator is and which operational functions are available to communicate with, as well as present a menu to the operator that is specific to the selected operational function. This greatly reduces the time, energy and inefficiency of having to otherwise make the operator trek back and forth between each operational location and the control console. It also reduces the need to scroll through a number of menus to find the menus that are applicable to a specific operational function.

Although an exemplary embodiment as set forth herein contemplates an access device 1 that functions as an operator interface to the local operational functions, such as, for example, data collection or adjusting controls of the local operational function, such devices continue to undergo significant improvements in their programming flexibility and power and memory storage. Therefore, in another embodiment, it is contemplated to have the control logic 58 use the wireless connectivity via the communication logic 50 to upload database information from the main control system 16 (FIG. 1) and/or the operational function control 52 (FIG. 2.) The access device 1 further can include additional logic in the form of resident programming that would utilize the database information. For example, such resident software may include spreadsheet type software such as EXCEL™ to name but one example. The resident software may be commercially available programs or proprietary as noted herein above. Not only can the database information be available to the access device 1, but the database information could also be downloaded from the access device 1 to one or more workstations or other operational functions throughout a facility. For example, this would avoid the need for Intranet and Extranet systems or other communication networks between the central control and distributed workstations, particularly for those users that do not want to use such networks that can sometimes be compromised on security.

Examples of the use of such an alternative embodiment include but are not limited to the following:

a. Collect run-time (or setup or other) information into spreadsheet. The spreadsheet could be used with any commercially available PDA resident spreadsheet program. Or, the PDA could be synchronized with another workstation or computer network so that the spreadsheet could be used with Excel or some other common workstation based spreadsheet system.

b. Collect alarm logs and store in the Calendar portion of the PDA system so that the user can see problems that occurred that day.

c. Develop a PDA resident QA program that will collect alarm data and provide Paredo charts and SPC (Statistical Process Control) information or other small graphic representations for better and easier diagnostics of the system.

As used herein, “PDA” or “Personal Data Assistant” is used generically and is used interchangeably with “general purpose PDA.” A PDA of the present invention is a general purpose computing machine sized and shaped to generally fit into a hand of a user. A “general purpose computing machine” as used herein is a computer which is designed to perform different, multiple and varying software applications as are generally available, such as, for example, e-mail, image viewing, calendar, address book, spreadsheet and word processing, and which is not specifically designed or adapted for a single purpose, use and/or implementation. A PDA of the present invention runs any suitable operating system, including but not limited to any version of the Palm OS™ and Windows CE™. Exemplary PDA's of the present invention include but are not limited to the Palm Tungsten™ and Zire™ lines, the Toshiba Pocket PC line and the Hewlett Packard iPAQ™ line, and further include PDA and phone combination devices, such as, e.g., the Handspring Treo™ line. Generally speaking, a PDA of the present invention is generally commercially available in that it is not the product of a special order or design customization. A PDA generally has a display screen and at least one user input mechanism, including but not limited to a touch screen functional with an electronic stylus.

As used herein, “logic” is used generically and includes but is not limited to hardware, software and/or combinations of both to perform a function.

As used herein, “software” is used generically and includes but is not limited to one or more computer executable instructions, routines, algorithms, modules or programs including separate applications and from dynamically linked libraries for performing functions as described herein. Software may also be implemented in various forms such as a servlet, applet, stand-alone, plug-in or other type of application. Software can be maintained on various computer readable mediums as known in the art.

As used herein, “network” is used generically and includes but is not limited to the Internet, intranets, Virtual Private Networks, Wide Area Networks and Local Area Netoworks.

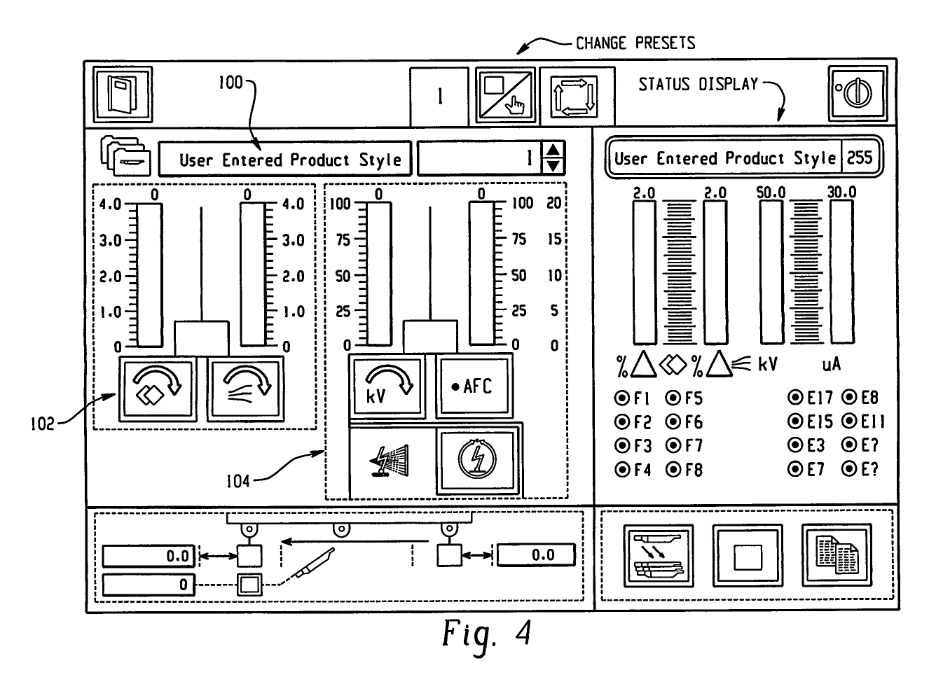

With reference to FIGS. 3A and 3B, an operator may make selections by actuation of the access device 1 via a keypad 200 or other input process. A keypad encoder 202 converts key selections to an appropriate code that is further encoded and transmitted by an encoder/transmitter 204a as an RF signal via an RF antenna 206a, or transmitted by an encoder/driver circuit 204b as an IR signal via an IR transmitter 206b. The RF signal is transmtted via the antenna 206a to the receiver antenna 208, and the IR signal is detected by an infrared receiver 209. The IR or RF signal is decoded by a second decoder 213 into the encoded key signal. A third decoder 210 converts the key command to appropriate instructions or control signals to the selected subsystem, such as the spray controller or other controllers 215a, b.

The specific designs of the encoders and decoders may be conventional or specific to a particular application. For example, the access device 1 may use standard wireless transmission protocols and circuits commonly used with wireless control devices.

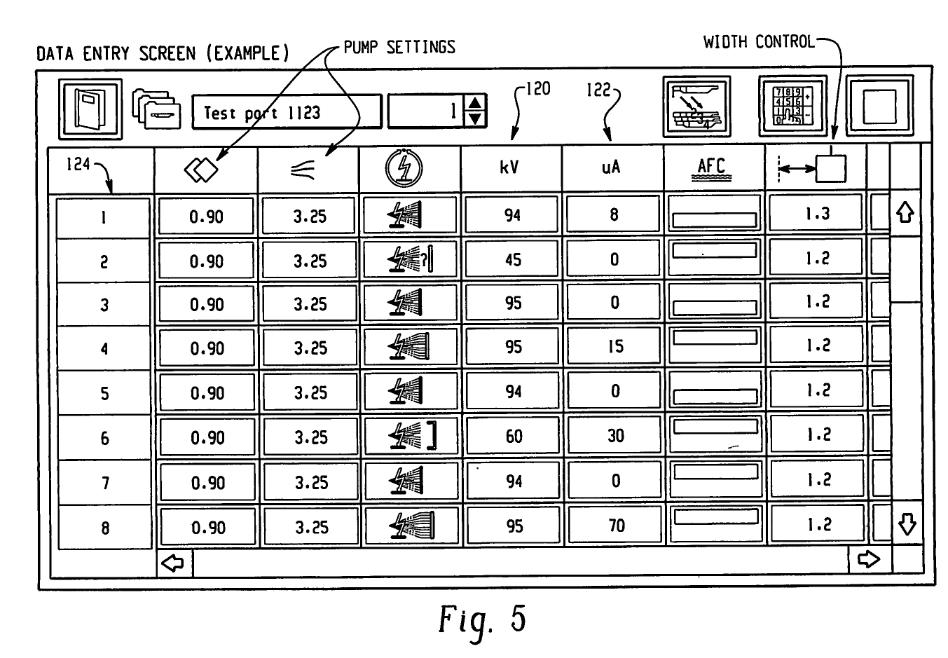

FIG. 4 illustrates an exemplary screen that may be presented to an operator by the access device 1 after the device has identified an established communication with an operational function, or the operator has made a selection of one of a plurality of available operational functions. The access device 1 may allow touch screen interface (such as with a stylus), pushbutton, keypad and so on as required. In the example of FIG. 4, the operator has access to control a product input selection 100, spray pattern selections 102, power settings 104, and so on.

FIG. 5 illustrates an exemplary screen that may be presented to an operator for data collection, diagnostics and so on. Again, the particular screen and data can be customized as required, but in accordance with the invention is directly associated with the operational function being accessed at that time. In the example of FIG. 5, the operator can change data such as voltage 120, current 122 for a plurality of spray guns 124.

The invention has been described with reference to the preferred embodiment. Obviously, modifications and alterations will occur to others upon a reading and understanding of this specification. It is intended to include all such modifications and alterations insofar as they come within the scope of the appended claims or the equivalents thereof.

1. A material application system comprising:
at least one application device at a first operational location and that when operational applies a material to a surface in accordance with a first operational function;
one or more additional operational locations, each said additional operational location being physically separated from each other and said application device first location by distances such that an operator traverses between said locations; each said one or more additional operational locations having an associated operational function located thereat; each associated operational function having an operator access function;
a respective wireless communication identifier associated with said application device and each said operational function at each said additional operational location and said application device first location; each said identifier having a unique identification associated therewith that can be communicated in a wireless manner;
a wireless access device that when used by an operator detects said identifiers.

2. The system of claim 1 wherein said access device comprises a hand held device.

3. The system of claim 2 wherein said hand held device is selected from the following group: PDA, notebook personal computer; tablet personal computer.

4. The system of claim 1 comprising a wireless network that provides wireless connectivity between each said identifier and said access device.

5. The system of claim 4 wherein said network is selected from the following group: infrared, radio frequency, IEEE 802, LAN, WAN, VPN, intranet, Internet.

6. The system of claim 1 wherein said access device operates on proximity based detection of each said identifier.

7. The system of claim 1 wherein said access device comprises identification logic that recognizes an identifier when said access device is within a sensing distance thereof.

8. The system of claim 7 wherein said access device comprises control logic that presents a visual display to the operator that is associated with a recognized identifier and its associated operational function.

9. The system of claim 7 wherein said access device comprises selection logic that provides a visual display for an operator to select an operational function when two or more said identifiers are detected.

10. The system of claim 1 wherein said access device comprises override logic that provides a control display for an operator to control one or more of said operational functions when beyond a sensing distance thereof.

11. The system of claim 1 wherein said application device comprises a powder spray gun and said additional operational functions include one or more of the following: feed center, cyclone, after filter, spray gun mover, part identification.

12. The system of claim 1 wherein said application device comprises a liquid dispensing device.

13. A method for controlling a material application system, comprising the steps of:
providing two or more material application operational functions with each said operational function being located at a respective operational location so that at least two of said operational locations are physically separated from each other by a distance such that an operator traverses said distance between said locations;
associating a unique wireless identifier with each said operational function;
using wireless connectivity for an operator to detect each identifier.

14. The method of claim 11 comprising the step of presenting a display to the operator that is uniquely associated with a detected identifier.

15. The method of claim 11 comprising the step of controlling operation of one or more of the following upon detection of an associated identifier: powder spray gun, powder feed center, after filter, spray gun mover, liquid dispensing gun.

16. A material application system comprising:
at least one application device at a first operational location and that when operational applies a material to a surface in accordance with a first operational function;
one or more additional operational locations, each said additional operational location being physically separated from each other and said application device first location by distances such that an operator traverses between said locations; each said one or more additional operational locations having an associated operational function located thereat; each associated operational function having an operator access function;
a respective operational function identifier associated with said application device and each said operational function at each said additional operational location and said application device first location; each said identifier having a unique identification associated therewith that can be communicated;
an access device that when used by an operator detects said identifiers and presents a menu to the operator that is associated with said detected identifier and related operational function.

17. The system of claim 14 wherein said access device is selected from the following group: PDA, notebook personal computer, tablet personal computer.

18. The system of claim 14 wherein said access device comprises a wireless hand held device.

19. The system of claim 14 wherein said access device plugs into a respective communication cradle positioned at one of said operational locations.
